(19) United States
(12) Patent Application Publication
(10) Pub. No.: US 2022/0319823 A1
(43) Pub. Date: Oct. 6, 2022

(54) Sputtering Target And Method For Manufacturing The Same

(71) Applicant: JX Nippon Mining & Metals Corporation, Tokyo (JP)

(72) Inventors: Jun Kajiyama, Ibaraki (JP); Yoshitaka Tsuruta, Ibaraki (JP)

(21) Appl. No.: 17/587,058

(22) Filed: Jan. 28, 2022

(30) Foreign Application Priority Data
Apr. 5, 2021 (JP) 2021-064478

(51) Int. Cl. H01J 37/34; C01G 15/00; C01G 19/00; C01G 9/00

(52) U.S. Cl. CPC H01J 37/3426; C01G 15/006; C01G 19/006; C01G 9/006; C01P 2006/90

(57) ABSTRACT

A ceramic sputtering target, wherein when a cross-sectional structure of a sputtering surface is observed with an electron microscope, an amount of microcracks defined below is 50 μm/mm or less, and after performing a peel test on the sputtering surface, an area ratio of peeled particles confirmed by observing the cross-sectional structure with an electron microscope is 1.0% or less.

Amount of microcracks=frequency of microcracks×average depth of microcracks

### CROSS REFERENCE TO RELATED APPLICATIONS

The present invention claims the benefit of priority to Japanese Patent Application No. 2021-064478 filed on Apr. 5, 2021 with the Japanese Patent Office, the entire contents of which are incorporated herein by reference in its entirety.

### FIELD OF THE INVENTION

The present invention relates to a sputtering target and a method for manufacturing the same.

### BACKGROUND OF THE INVENTION

Sputtering is one of the methods for forming thin films for semiconductor devices. As a sputtering target (hereinafter, also simply referred to as “target”) used for sputtering, those made of ceramics are known. A target material made of ceramics is obtained by molding and sintering powders or particles containing a ceramic component such as a metal oxide and machining the sintered body into a predetermined size by cutting or polishing.

In recent years, miniaturization in the nanotechnology fields has progressed, and the control of substrate particles has become more and more strict in sputtering. Therefore, it is necessary to review the methods that have been implemented for many years and take measures that will lead to the reduction of substrate particles during sputtering.

It is known that the processing accuracy of the sputtering target material affects the quality of the thin film (sputtered film) formed on the surface of a substrate. Therefore, regarding the processing of a sputtering target material made of ceramics, measures for improving the quality of the thin film have been studied.

On the surface of ceramic sputtering targets such as ITO and IZO, there is a processing damage layer that occurs during machining of the target, and minute cracks (hereinafter, also referred to as “microcracks”) of about 0.1 to several tens of μm exist. When a large number of these microcracks are present on the surface, the target strength in the vicinity of the microcracks becomes locally brittle, and particles on the target surface are easily peeled off during target sputtering, which causes particles and also nodules. In particular, it is considered that the above abnormality is likely to occur in the initial stage of use of the target whose machined surface of the target is exposed on the surface.

Patent Literature 1 (WO 2016/027540) discloses a target material, which is a flat plate-shaped ceramic, wherein a surface roughness Ra of a sputtering surface to be subjected to sputtering is 0.5 μm or more and 1.5 μm or less, and a maximum depth of cracks formed on the sputtering surface is 15 μm or less. It is described that if the Ra is less than 0.5 μm, nodules generated by the target material during sputtering adhere to the sputter film as particles instead of staying in the target material, and the quality of the sputter film tends to deteriorate. It is also described that if the maximum depth of cracks exceeds 15 μm, nodules are more likely to occur during sputtering and may affect the mechanical strength of the target material.

Patent Literature 2 (Japanese Patent Application Publication No. 2004-204356) discloses an ITO sputtering target, characterized in that a number of adhered particles having an average diameter of 0.2 μm or more existing in an area of 100 μm×100 μm on a surface to be sputtered obtained by performing multiple oscillation ultrasonic cleaning on a sputtering surface of an ITO sputtering target sintered body is 400 or less. In Patent Literature 2, the ITO sputtering target is generally obtained by grinding a sintered body with a lathe or the like, and based on the speculation that the ITO grinding powder adhering to the target surface is one of the causes of the generation of nodules, the ITO grinding powder is removed by ultrasonic cleaning, or the ITO grinding powder is removed by peeling with an adhesive tape. By doing so, the surface of the target will be further cleaned, so that an ITO sputtering target for forming a transparent conductive film in which nodules are less generated during film formation by sputtering and abnormal discharge and particles are less likely to occur will be provided.

### PRIOR ART

### Patent Literature

[Patent Literature 1] WO 2016/027540
[Patent Literature 2] Japanese Patent Application Publication No. 2004-204356

### SUMMARY OF THE INVENTION

In Patent Literature 1, instead of surface grinding the ceramic sintered body, the ceramic sintered body is cut and the cut surface is used as the sputtering surface to suppress the generation of microcracks. On the other hand, there is insufficient study on suppressing microcracks when a ceramic sintered body is surface ground. Further, when the cut surface is the sputtering surface, it is not suitable for manufacturing a target having a large area, and the use of the target is naturally limited.

In Patent Literature 2, the effect of suppressing abnormal discharge and generation of particles is obtained by removing the grinding powder. However, apart from the grinding powder, particles due to microcracks are also generated, so another approach is desired. In Patent Literature 2, studies on suppressing the occurrence of microcracks are insufficient.

The present invention has been made in view of such circumstances, and an object of the present invention is to provide a sputtering target capable of suppressing the amount of nodules generated which leads to an increase in substrate particles during sputtering, and a method for manufacturing the same.

As a result of diligent studies by the present inventor, the present inventors have found that the amount of microcracks on the sputtering surface of a sputtering target (an indicator taking into consideration both the number and depth of microcracks) is closely related to the generation of nodules which leads to an increase in substrate particles. Further, it is discovered that by appropriately controlling the amount of microcracks on the sputtering surface of a sputtering target and/or the amount of peeling of deposits on the sputtering surface of the sputtering target, the generation of fine nodules at the initial stage of use can be significantly reduced. Accordingly, the present invention is specified as follows.

[1] A ceramic sputtering target, wherein when a cross-sectional structure of a sputtering surface is observed with an electron microscope, an amount of microcracks defined below is 50 μm/mm or less, and an area ratio of peeled particles from the sputtering surface confirmed by a peel test under the following conditions is 1.0% or less.

### Amount of Microcracks:

In order to evaluate the machining damage (microcracks) that occur on the outer surface of the machined surface of the target (=the sputtering surface of the final product), the side surface (cross section perpendicular to the machined surface of the target) when the machined surface is on the upside is used as the observation surface. The observation surface is mirror-polished by rough polishing with sandpaper and buffing with a liquid polishing material using colloidal SiO₂, Al₂O₃, and the like as a medium. The vicinity of the outer surface of the mirror-polished surface is observed along the sputtering surface using FE-SEM (JSM-6700F) manufactured by JEOL Ltd. Counting is repeated until 20 microcracks having a crack starting point on the sputtering surface and with a depth (=maximum vertical distance from the sputtering surface) of 0.1 μm or more are confirmed. By dividing the number of 20 by the total length L from the first microcrack to the 20th microcrack, it is converted into the number of microcracks per 1 mm in length of the upper end portion on the sputtering surface side. This is defined as the frequency of the microcracks occurrence. In addition, the vertical depth from the sputtering surface is calculated for each of the microcracks based on the image observed by the electron microscope and the scale. The average D (=[D1+D2+D3+ . . . +D20]/20) of the calculated depths for the 20 microcracks is taken as the average depth of the microcracks. The product of the frequency of the microcracks occurrence and the average depth of the microcracks is defined as the amount of the microcracks (see FIG. 6).

### Peel Test Conditions:

A double-sided carbon tape is attached to the sputtering surface of the target, and the attached portion is rubbed with thumb for about 2 seconds to attach the peeled particles on the target surface to the carbon tape (the area of attachment is set as 100 mm² or more). The above operation is performed three times on the attachment surface of the tape on the same surface of the target (the same tape is attached and peeled off at arbitrary three different places on the surface). The surface (100 mm² or more) of the tape which has been attached to the target is used as an observation surface for observation and photography with an electron microscope, and the area ratio of adhered particles on the observation surface is calculated by an image processing software. The average value of the three fields of view of the same carbon tape sample observed by the above method is defined as the area ratio of the peeled particles by the peel test.
[2] The ceramic sputtering target according to [1], wherein the amount of microcracks is 40 μm/mm or less.
[3] The ceramic sputtering target according to [1], wherein the amount of microcracks is 30 μm/mm or less.
[4] The ceramic sputtering target according to any one of [1] to [3], wherein the area ratio of the peeled particles is 0.5% or less.
[5] The ceramic sputtering target according to any one of [1] to [3], wherein the area ratio of the peeled particles is 0.3% or less.
[6] The ceramic sputtering target according to any one of [1] to [5], wherein a surface roughness Ra of the sputtering surface is 0.05 to 0.50 μm.
[7] The ceramic sputtering target according to any one of [1] to [6], comprising at least one of In, Zn, Al, Ga, Zr, Ti, Sn, Mg, Ta, Sm and Si.
[8] The ceramic sputtering target according to any one of [1] to [7], which is an IZO with a Zn content of 1 to 15% by mass in terms of ZnO.
[9] The ceramic sputtering target according to any one of [1] to [7], which is an ITO with a Sn content of 1 to 15% by mass in terms of SnO₂.
[10] The ceramic sputtering target according to any one of [1] to [7], which is an IGZO with an In content of 10 to 60% by mass in terms of In₂O₃, a Ga content of 10 to 60% by mass in terms of Ga₂O₃, and a Zn content of 10 to 60% by mass in terms of ZnO.
[11] The ceramic sputtering target according to any one of [1] to [7], which is an AZO with an Al content of 0.1 to 5% by mass in terms of Al₂O₃.
[12] A method for manufacturing a ceramic sputtering target, comprising:
a step of preparing a ceramic sintered body;
a step of surface grinding the ceramic sintered body using a sponge polishing material having a count of #300 or more and #1000 or less; and
a step of forming a sputtering surface by finishing processing the ceramic sintered body using a vibration tool after the surface grinding.
[13] The method for manufacturing a ceramic sputtering target according to [12], wherein when a cross-sectional structure of the sputtering surface after the finishing processing is observed with an electron microscope, an amount of microcracks defined below is 50 μm/mm or less, and after performing a peel test on the sputtering surface, an area ratio of peeled particles confirmed by observing the cross-sectional structure with an electron microscope is 1.0% or less.

Amount of microcracks=frequency of microcracks×average depth of microcracks

[14] The method for manufacturing a ceramic sputtering target according to [13], wherein the amount of microcracks is 40 μm/mm or less.
[15] The method for manufacturing a ceramic sputtering target according to [13], wherein the amount of microcracks is 30 μm/mm or less.
[16] The method for manufacturing a ceramic sputtering target according to any one of [13] to [15], wherein the area ratio of the peeled particles is 0.5% or less.
[17] The method for manufacturing a ceramic sputtering target according to any one of [13] to [15], wherein the area ratio of the peeled particles is 0.3% or less.
[18] The method for manufacturing a ceramic sputtering target according to any one of [12] to [17], wherein a surface roughness Ra of the sputtering surface after the finishing processing is 0.05 to 0.50 μm.
[19] The method for manufacturing a ceramic sputtering target according to any one of [12] to [18], wherein the ceramic sputtering target comprises at least one of In, Zn, Al, Ga, Zr, Ti, Sn, Mg, Ta, Sm and Si.
[20] The method for manufacturing a ceramic sputtering target according to any one of [12] to [19], wherein the ceramic sputtering target is an IZO with a Zn content of 1 to 15% by mass in terms of ZnO.
[21] The method for manufacturing a ceramic sputtering target according to any one of [12] to [19], wherein the ceramic sputtering target is an ITO with a Sn content of 1 to 15% by mass in terms of SnO₂.
[22] The method for manufacturing a ceramic sputtering target according to any one of [12] to [19], wherein the ceramic sputtering target is an IGZO with an In content of 10 to 60% by mass in terms of In₂O₃, a Ga content of 10 to 60% by mass in terms of Ga₂O₃, and a Zn content of 10 to 60% by mass in terms of ZnO.
[23] The method for manufacturing a ceramic sputtering target according to any one of [12] to [19], wherein the ceramic sputtering target is an AZO with an Al content of 0.1 to 5% by mass in terms of Al₂O₃.

According to the present invention, it is possible to provide a sputtering target capable of suppressing the amount of fine nodules generated which leads to an increase in substrate particles during sputtering, and a method for manufacturing the same.

### BRIEF DESCRIPTION OF THE DRAWINGS

FIG. 1 is a process flow showing a method for manufacturing a sputtering target according to an embodiment of the present invention.

FIG. 2 is a diagram showing a cause of microcracks on a target surface during machining with a surface grinding machine using a grindstone.

FIG. 3 is a diagram showing a method of performing surface grinding using a sponge polishing material in some embodiments of the present disclosure.

FIG. 4 is a diagram showing a method of observing microcracks.

FIG. 5 is a diagram showing the number of particles generated throughout the sputter life.

FIG. 6 is a diagram showing the method of calculating the average depth of microcracks.

### DETAILED DESCRIPTION OF THE INVENTION

Hereinafter, embodiments of the present invention will now be described. It should be understood that the present invention is not intended to be limited to the following embodiments, and any change, improvement or the like of the design may be appropriately added based on ordinary knowledge of those skilled in the art without departing from the spirit of the present invention.

### (1. Sputtering Target)

In the present embodiment, the shape of the sputtering target is not particularly limited, and may be any shape such as a flat plate shape or a cylindrical shape as long as it has a sputtering surface. A flat plate shape is preferable. The sputtering surface is the surface on which sputtering should be performed as a product.

In cases where the sputtering target is flat plate shape, it usually has a backing plate to support it. As the backing plate, those conventionally used can be appropriately selected and used. For example, stainless steel, titanium, titanium alloys, copper and the like can be applied, but the present invention is not limited them. The backing plate is usually bonded to the sputtering target via a bonding material, and those conventionally used can be appropriately selected and used as the bonding material. For example, indium metal and the like can be mentioned, but the present invention is not limited to this.

The sputtering target according to the present embodiment may be any material as long as it is made of a ceramic sintered body, and its composition is not particularly limited.

The composition of the ceramic sintered body constituting the sputtering target is not particularly limited, but for example, mention can be made to an oxide comprising at least one of In, Zn, Al, Ga, Zr, Ti, Sn, Mg, Ta, Sm and Si, and the like. Specifically, examples may include, but not limited to, an ITO (In₂O₃—SnO₂) having a Sn content of 1 to 15% by mass in terms of SnO₂, an IZO (In₂O₃—ZnO) having a Zn content of 1 to 15% by mass in terms of ZnO, an IGZO (In₂O₃—Ga₂O₃—ZnO) with an In content of 10 to 60% by mass in terms of In₂O₃, a Ga content of 10 to 60% by mass in terms of Ga₂O₃, a Zn content of 10 to 60% by mass in terms of ZnO, and an AZO (Al₂O₃—ZnO) having an Al content of 0.1 to 5% by mass in terms of Al₂O₃, and the like.

In addition, the ceramic sintered body is usually subjected to processing such as surface grinding after sintering. Although the details will be described later, in one aspect of the present disclosure, a finishing process is performed using a vibration tool even after the surface grinding is performed. In this specification, the one before a finishing process is referred to as a ceramic sintered body, and the one after the finishing process is referred to as a sputtering target.

In the ceramics sputtering target of the present disclosure, when a cross-sectional structure of a sputtering surface is observed with an electron microscope, an amount of microcracks defined below is 50 μm/mm or less.

Amount of microcracks=frequency of microcracks×average depth of microcracks

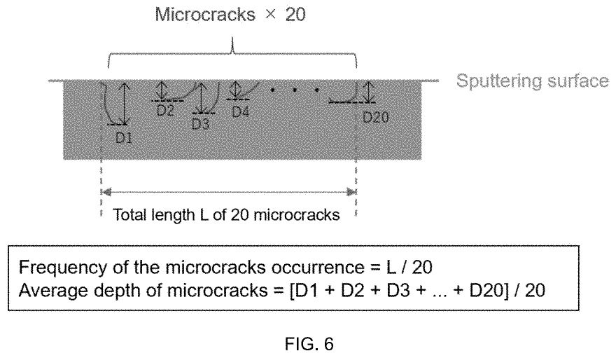

The frequency of microcracks occurrence is expressed as the number of microcracks per 1 mm in length of the upper end portion on the sputtering surface side in the observation of the cross-sectional structure. Specifically, in order to evaluate the machining damage (microcracks) that occur on the outer surface of the machined surface of the target (=the sputtering surface of the final product), the side surface (cross section perpendicular to the machined surface of the target) when the machined surface is on the upside is used as the observation surface. The observation surface is mirror-polished by rough polishing with sandpaper and buffing with a liquid polishing material using colloidal SiO₂, Al₂O₃, and the like as a medium. The vicinity of the outer surface of the mirror-polished surface is observed along the sputtering surface using FE-SEM (JSM-6700F) manufactured by JEOL Ltd. Counting is repeated until 20 microcracks having a crack starting point on the sputtering surface and with a depth (=maximum vertical distance from the sputtering surface) of 0.1 μm or more are confirmed. By dividing the number of 20 by the total length L from the first microcrack to the 20th microcrack, it is converted into the number of microcracks per 1 mm in length of the upper end portion on the sputtering surface side. This is defined as the frequency of the microcracks occurrence. In addition, the vertical depth from the sputtering surface is calculated for each of the microcracks based on the image observed by the electron microscope and the scale. The average D (=[D1+D2+D3+ . . . +D20]/20) of the calculated depths for the 20 microcracks is taken as the average depth of the microcracks. The product of the frequency of the microcracks occurrence and the average depth of the microcracks is defined as the amount of the microcracks (see FIG. 6).

By reducing the amount of microcracks on the surface of the sputtering target, it is possible to suppress the generation of particles and nodules during sputtering (particularly at the initial stage), and stable sputtering can be performed. From this point of view, the amount of microcracks on the sputtering surface is preferably 45 μm/mm or less, more preferably 40 μm/mm or less, even preferably 35 μm/mm or less, even more preferably 30 μm/mm or less, even more preferably 25 μm/mm or less, and even more preferably 20 μm/mm or less.

No lower limit is set for the amount of microcracks on the surface of the sputtering target. When observing the cross-sectional structure on the sputtering surface, the amount of microcracks may be 0 μm/mm. However, if the amount of microcracks is extremely reduced, the cost and labor will increase but the effect reaches a plateau, so the amount of microcracks may be, for example, 1 μm/mm or more, or 5 μm/mm or more, or 10 μm/mm or more, or 15 μm/mm or more, depending on the actual need.

Further, the maximum value of the depth of each microcrack measured as described above is preferably 4 μm or less. By suppressing not only the amount of microcracks but also the maximum depth of microcracks, the generation of nodules during sputtering can be further reduced. From this point of view, the maximum depth of microcracks is more preferably less than 4 μm, even more preferably 3.8 μm or less, even more preferably 3.5 μm or less, even more preferably 3.0 μm or less, even more preferably 2.8 μm or less, and even more preferably 2.5 μm or less.

Further, in the ceramics sputtering target of the present disclosure, in one embodiment, after performing a peel test on the sputtering surface under the following conditions, when a tape attachment surface is observed with an electron microscope, an area ratio of peeled particles is 1.0% or less.

A double-sided carbon tape is attached to the sputtering surface of the target, and the attached portion is rubbed with thumb for about 2 seconds to attach the peeled particles on the target surface to the carbon tape (the area of attachment is set as 100 mm² or more). The above operation is performed three times on the attachment surface of the tape on the same surface of the target (the same tape is attached and peeled off at arbitrary three different places on the surface). The surface (100 mm² or more) of the tape which has been attached to the target is used as an observation surface for observation and photography with an electron microscope, and the area ratio of adhered particles on the observation surface is calculated by an image processing software. The average value of the three fields of view of the same carbon tape sample observed by the above method is defined as the area ratio of the peeled particles by the peel test.

In the present invention, a carbon tape for SEM manufactured by Nissin EM Co., Ltd. (Product No. 732) is used as the double-sided carbon tape, and as a photograph for evaluating the area ratio of the peeled particles, a 100-fold magnification backscattered electron composition image taken by FE-SEM (JSM-6700F) manufactured by JEOL Ltd. is used. It is binarized with an image processing software ImageJ. The average value of the three fields of view of the same carbon tape sample observed by the above method is defined as the area ratio of the peeled particles by the peel test.

By reducing the amount of depositions on the surface of the sputtering target, it is possible to suppress the generation of particles and nodules during sputtering (particularly at the initial stage), and stable sputtering can be performed. From this point of view, after performing the peel test on the sputtering surface, when the tape attachment surface is observed with an electron microscope, the area ratio of the peeled particles is more preferably 0.9% or less, even more preferably 0.8% or less, even more preferably 0.7% or less, even more preferably 0.6% or less, even more preferably 0.5% or less, even more preferably 0.4% or less, even more preferably 0.3% or less, even more preferably 0.2% or less, and even more preferably 0.1% or less.

No particular lower limit is set for the area ratio of the peeled particles after the peel test. After performing the peel test on the sputtering surface, when the tape attachment surface is observed with an electron microscope, the area ratio of the peeled particles may be 0%. However, if the area ratio of the peeled particles is extremely reduced, the cost and labor will increase but the effect reaches a plateau. The area ratio of the peeled particles after the peel test may be, for example, 0.001% or more, or 0.01% or more, or 0.05% or more, or 0.1% or more, or 0.15% or more, or 0.20% or more, depending on the actual need.

In one embodiment, the ceramic sputtering target of the present disclosure preferably has a surface roughness Ra of the sputtering surface of 0.05 to 0.50 μm. When the surface roughness Ra of the sputtering surface is 0.50 μm or less, the physical strength of the sputtering surface of the target is sufficiently improved, and the peeling of surface particles during sputtering can be reduced. From this point of view, the surface roughness Ra of the sputtering surface is more preferably less than 0.50 μm, even more preferably 0.40 μm or less, even more preferably 0.30 μm or less, even more preferably 0.20 μm or less, and even more preferably 0.10 μm or less.

On the other hand, where there are non-eroded portions (non-erosion portion) on the sputtering surface of the sputtering target, it is desirable not to peel off or scatter the film or powder adhering to the non-erosion portions during sputtering. From this point of view, considering the adhesion between the sputtering surface of the sputtering target and the film or powder, it is considered that a state of being too smooth is not preferable. In fact, it has been confirmed that when Ra is less than 0.05 μm, the film or powder adhering to non-erosion portions is easily peeled off and scattered, which affects the number of particles on a substrate. Therefore, the surface roughness Ra of the sputtering surface of the sputtering target is preferably 0.05 μm or more, more preferably 0.07 μm or more, even more preferably 0.10 μm or more, even more preferably 0.12 μm or more, and even more preferably 0.15 μm or more.

In addition, the surface roughness Ra means “arithmetic mean roughness Ra” according to JIS B0601: 2013. A stylus type surface roughness meter is used for the measurement.

### (2. Method for Manufacturing Sputtering Target)

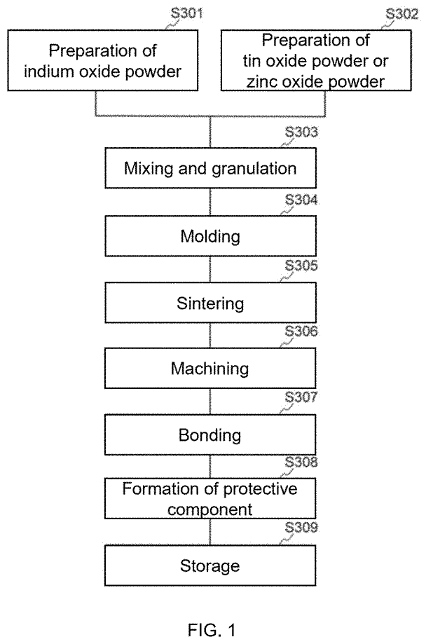

Next, a method for manufacturing the sputtering target according to the present invention will be described by taking an IZO or ITO sputtering target as an example. FIG. 1 is a process flow showing a method for manufacturing a sputtering target according to an embodiment of the present invention.

First, raw materials for constituting a sintered body are prepared. In the present embodiment, indium oxide powder and zinc oxide powder (in the case of ITO, tin oxide powder) are prepared (S301, S302). The purity of these raw materials is usually 2N (99% by mass) or higher, preferably 3N (99.9% by mass) or higher, and more preferably 4N (99.99% by mass) or higher. If the purity is lower than 2N, the sintered body 120 contains a large amount of impurities, so that there may be a problem that the desired physical properties cannot be obtained (for example, the transmittance of the formed thin film may be reduced, the resistance value may be increased, and particles may be generated due to arcing).

Next, the powders of these raw materials are crushed and mixed (S303). For the crushing and mixing process of the raw material powder, a dry method using balls or beads (so-called media) such as zirconia, alumina, nylon resin, and the like, or a wet method such as a media stirring mill using the balls and beads, a medialess container rotary mill, a mechanical stirring mill, and an air flow mill can be used. Here, since a wet method is generally superior in pulverization and mixing ability as compared with a dry method, it is preferable to perform mixing by using a wet method.

The composition of the raw material is not particularly limited, but it is desirable to appropriately adjust the composition according to the composition ratio of the target sintered body.

Next, the slurry of the raw material powder is dried and granulated (S303). At this time, the slurry may be rapidly dried using rapid drying granulation. Rapid drying granulation may be performed by using a spray dryer and adjusting the temperature and air volume of hot air.

Next, the mixture obtained by the above-mentioned mixing and granulation (if calcination is performed, the calcinated body) is filled in a mold having a desired shape, and pressure-molded into a flat plate shape. (S304). By this step, it is formed into a shape suitable for the target sintered body. In the molding process, the molding pressure can be controlled to form a molded body having a relative density of 54.5% or more and 58.0% or less. By setting the relative density of the molded product in the above range, the relative density of the sintered body obtained by the subsequent sintering can be controlled to 99.7% or more and 99.9% or less. After obtaining the molded product, it may be further molded by cold isotropic pressurization (CIP).

Next, the flat plate shape molded body obtained in the molding step is sintered (S305). An electric furnace is used for sintering. The sintering conditions can be appropriately selected depending on the composition of the sintered body. For example, an ITO containing 10% by mass of SnO₂ can be sintered by placing it in an oxygen gas atmosphere at a temperature of 1400° C. or higher and 1600° C. or lower for 10 hours or more and 30 hours or less. If the sintering temperature is lower than the lower limit, the relative density of the sintered body will decrease. On the other hand, if the temperature exceeds 1600° C., the electric furnace and the furnace material are significantly damaged and frequent maintenance is required, so that the work efficiency is significantly reduced. Further, if the sintering time is shorter than the lower limit, the relative density of the sintered body 120 will decrease.

Next, machining is performed to form the sputtering surface of the sintered body (S306). Generally, the surface machining of a sputtering target is performed by grinding with a grindstone using a surface grinding machine. According to the research of the present inventors, it is possible to suppress the processing damage to the target and reduce the microcracks by slowing down the feed rate of the grinding wheel and reducing the depth of cut. However, changing the processing conditions with this grindstone is not sufficient, and many surface microcracks remain, so it has been confirmed that a large number of particles at initial stage are generated during sputtering of the target.

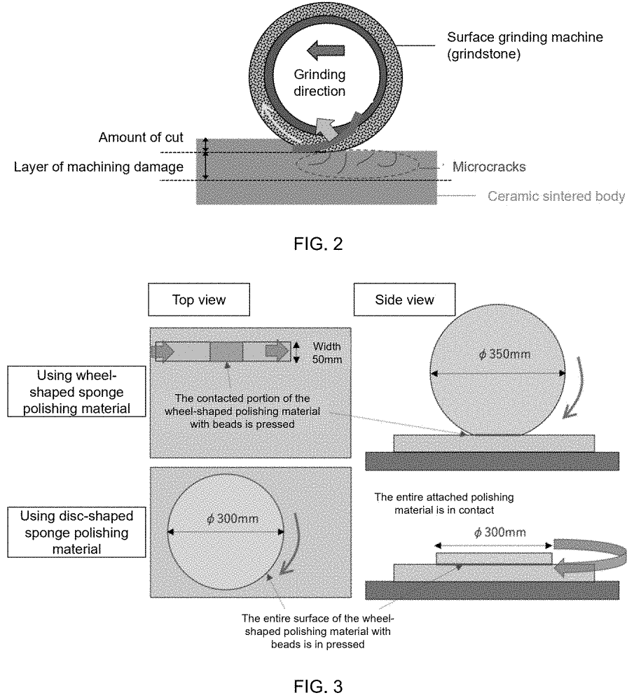

Specifically, as shown in FIG. 2, when machining with a grindstone, grinding is performed so that the surface grinding machine (grindstone) rotates (curved arrow) and scoops out the surface layer of the target. Therefore, in the processing of ceramic sputtering targets that are not malleable, it is considered that new microcracks are likely to occur during the processing.

Accordingly, in one embodiment of the present disclosure, in performing machining, after a mechanical grinding process with a normal grindstone, by grinding the final target surface with a sponge polishing material instead of a grindstone, low processing damage processing is performed to reduce the depth and frequency of microcracks on the target surface. In addition, after grinding, a vibration tool described later is used to perform a finishing process by applying minute vibration to the target surface to remove minute particles that are easily peeled off from the target surface after the machining. As the polishing material attached to the vibration tool, a sponge polishing material may also be used.

Specifically, the sponge polishing material used for polishing has a count of #300 or more and #1000 or less. Preferably, the first step is polishing with a coarse sponge polishing material of #300 to #600, and the second step is finishing polishing with a fine sponge polishing material of #600 to #1000, thereby reducing the labor of processing, and it is possible to obtain the effects of the invention. As a result, the depth and frequency of microcracks on the sputtering surface can be reduced, and the amount of microcracks can be reduced. In addition, the area ratio of the peeled particles on the target surface by the peel test can be reduced.

Accordingly, one embodiment of the present disclosure provides a method for manufacturing a ceramic sputtering target, the method comprising:

a step of preparing a ceramic sintered body;
a step of surface grinding the ceramic sintered body using a sponge polishing material having a count of #300 or more and #1000 or less; and
a step of forming a sputtering surface by finishing processing the ceramic sintered body using a vibration tool after the surface grinding.

Further, from the viewpoint of reducing the depth and frequency of occurrence of microcracks on the sputtering surface, the lower limit of the count of the sponge polishing material used for forming the final machined surface is preferably #600 or more, more preferably #700 or more, and even more preferably #800 or more. Regarding the upper limit of the count of the sponge polishing material used for polishing, if it is #1000 or less, the desired effect can be obtained, but depending on the need, it may be #950 or less, or #900 or less, or #850 or less. In this specification, the count refers to the particle size specified in JIS R6001-2: 2017.

FIG. 3 shows a method of performing surface grinding using a sponge polishing material in some embodiments of the present disclosure. In the upper part of FIG. 3, in surface grinding, a polishing wheel made of a sponge polishing material is used. At the time of grinding, the polishing wheel is placed above the ceramic sintered body so that the rotation axis of the polishing wheel is substantially parallel to the surface to be processed (the surface corresponding to the sputtering surface) of the ceramic sintered body. When the sponge polishing material and the surface to be processed of the ceramic sintered body come into contact with each other while the polishing wheel is rotated, the brush of the sponge polishing material is deformed and pressure is applied to the surface of the ceramic sintered body, so that the surface is ground. The amount of deformation of the brush made of the sponge polishing material corresponds to the amount of cut in the polishing wheel. In the illustrated embodiment, the area where the sponge polishing material mounted on the polishing wheel and the surface to be processed of the ceramic sintered body actually come into contact is 50 mm (equal to the width of the sponge polishing material)×about 60 mm. Needless to say, it is possible to optimize processing conditions such as the rate of rotations of the polishing wheel and the feed rate according to the count of grindstones and the concentration of abrasive grains.

The lower part of FIG. 3 shows surface grinding using a polisher equipped with a sponge polishing material. At the time of polishing, the polisher is placed above the ceramic sintered body so that the rotation axis of the polisher is substantially perpendicular to the surface to be processed (the surface corresponding to the sputtering surface) of the ceramic sintered body. When the sponge polishing material and the surface to be processed of the ceramic sintered body come into contact with each other while the polisher is rotated, pressure is applied to the surface of the ceramic sintered body, so that the surface is ground. In the illustrated embodiment, the sponge polishing material attached to the polisher is disk-shaped with a diameter of 300 mm when viewed from above, and during surface grinding, the entire disk-shaped sponge polishing material is in contact with the surface of the ceramic sintered body to be processed. Needless to say, the processing conditions such as the rate of rotations of the polisher and the feed rate can be optimized according to the count of grindstones and the concentration of abrasive grains.

The vibration tool used for finishing is a device that can generate minute vibrations with the sponge polishing material attached. By applying a minute vibration to the ceramic sintered body through the sponge polishing material, it is possible to peel off the minute deposits adhering to the target surface after the grinding process. These minute deposits can cause particles and nodules during sputtering (especially in the initial stages), so it is desirable to remove them by finishing process. The manufacturer and model number of the vibration tool to which the polishing material is attached, the vibration frequency and rotation speed, the presence or absence of dust absorbing function, or the like need not be limited to the above, and any vibration tool can be used. However, from the viewpoint of work efficiency, a vibration tool of the type called a double action sander is particularly preferable.

The composition of the ceramic sintered body constituting the sputtering target is not particularly limited, but for example, mention can be made to an oxide comprising at least one of In, Zn, Al, Ga, Zr, Ti, Sn, Mg, Ta, Sm and Si. Specifically, examples may include, but not limited to, an IZO (In₂O₃—ZnO) having a Zn content of 1 to 15% by mass in terms of ZnO, an ITO (In₂O₃—SnO₂) having a Sn content of 1 to 15% by mass in terms of SnO₂, an IGZO (In₂O₃—Ga₂O₃—ZnO) with an In content of 10 to 60% by mass in terms of In₂O₃, a Ga content of 10 to 60% by mass in terms of Ga₂O₃, a Zn content of 10 to 60% by mass in terms of ZnO, and an AZO (Al₂O₃—ZnO) having an Al content of 0.1 to 5% by mass in terms of Al₂O₃, and the like.

Further, other physical properties of the produced sputtering target are the same as described above.

### EXAMPLES

Hereinafter, description will be given based on Examples and Comparative Examples. It should be noted that the Examples are merely illustrative, and the present invention is not limited by the Examples. That is, the present invention is limited only by the scope of claims, and includes various modifications other than the Examples described in the present invention.

### Comparative Example 1

### <Surface Grinding Process>

An IZO plate shaped ceramic sintered body having a ZnO content of 10.7% by mass was prepared. One side of this ceramic sintered body was roughly ground with a surface grinding machine manufactured by OKAMOTO CORPORATION using a grindstone with a count of #80 under the conditions of a grindstone rotation speed of 1800 rpm, a depth of cut of 50 μm/pass, and a spark-out of 4 passes. Subsequently, using the same device and a grindstone of count #400, a fine grinding process was carried out under the conditions of a grindstone rotation speed of 1250 rpm, a depth of cut of 10 μm/pass, and a spark-out of 6 passes.

### Comparative Example 2

### <Surface Grinding Process>

A ceramic sintered body having the same composition as that of Comparative Example 1 was prepared, and surface grinding was performed under the same conditions as that of Comparative Example 1.

### <Finishing Process>

Next, a sponge polishing material (Scotch Brite 7448DOT manufactured by 3M) with a count of #800 was attached to a vibration tool (Orbital Sander U-62 manufactured by SAITAMA SEIKI CO., LTD.), and the surface that had been surface ground was finishing processed under the condition of a polishing time of 150 min/m². Note that the manufacturer and model number of the vibration tool to which the polishing material is attached, the vibration frequency and rotation speed, the presence or absence of dust absorbing function, or the like need not be limited to the above, and any vibration tool can be used.

### Comparative Example 3

### <Surface Grinding Process>

A ceramic sintered body having the same composition as that of Comparative Example 1 was prepared, and rough grinding process was performed under the same conditions as in Comparative Example 1 except that the count of the grindstone was changed to #800.

### Reference Example 1

### <Surface Grinding Process>

A ceramic sintered body having the same composition as that of Comparative Example 1 was prepared. First, as a pretreatment, a surface grinding process with a #400 grindstone was performed. Next, as a finishing, a sponge polishing material with a count of #500 was attached to a vibration tool (Orbital Sander U-62 manufactured by SAITAMA SEIKI CO., LTD.) to grind so that the thickness of the target became smaller than the original thickness by 15 μm or more, and then, as a finishing, a sponge polishing material with a count of #800 was attached to the same vibration tool, and the target was ground so that the thickness of the target was further smaller than that after grinding with the sponge polishing material of #500 by 2 μm or more. The condition of polishing time was 1000 min/m². It took a considerable amount of time to polish with the vibration tool by machining in order to remove the machining damage due to the #400.

### Comparative Example 4

### <Surface Grinding Process>

A ceramic sintered body having the same composition as that of Comparative Example 1 was prepared, and a disk-shaped sponge polishing material (φ 300 mm) with a count of #320 was attached to a Model SDK-P1000NC wet polishing device (polisher) manufactured by Sanwa Diamond Kohan Co., Ltd. to perform surface processing. The grinding conditions were set so that the polisher rotation speed was 120 rpm, the surface pressure (pressing pressure) on the machined surface was 0.58 g/mm², and the grinding time was about 300 min/m². Next, the disc-shaped sponge polishing material was changed to one of count #800, and surface processed under the same conditions.

### Example 1

### <Surface Grinding Process>

A ceramic sintered body having the same composition as that of Comparative Example 1 was prepared, and surface grinding was performed under the same conditions as that of Comparative Example 4.

### <Finishing Process>

A sponge polishing material (Scotch Brite 7448DOT manufactured by 3M) with a count of #800 was attached to a vibration tool (Orbital Sander U-62 manufactured by SAITAMA SEIKI CO., LTD.), and finishing process was performed under the condition of polishing time of 150 min/m².

### Comparative Example 5

### <Surface Grinding Process>

A ceramic sintered body having the same composition as that of Comparative Example 1 was prepared and surface processed with a Unilon flap wheel (polishing wheel) manufactured by YANASE Co., Ltd., which was composed of a sponge polishing material having a count of #320. As the grinding conditions, the wheel rotation speed was 10000 rpm and the depth of cut (=thickness of the polishing wheel overlapping the target when the height at the time of setting the target was 0) was 6 mm. Next, the count of the sponge polishing material constituting the polishing wheel was changed to one with count of #800, and surface processing was performed under the same conditions.

### Example 2

### <Surface Grinding Process>

A ceramic sintered body having the same composition as that of Comparative Example 1 was prepared, and surface grinding was performed under the same conditions as that of Comparative Example 5.

### <Finishing Process>

Next, a sponge polishing material (Scotch Brite 7448DOT manufactured by 3M) with a count of #800 was attached to a vibration tool (Orbital Sander U-62 manufactured by SAITAMA SEIKI CO., LTD.), and the surface that had been surface ground was finishing processed under the condition of a polishing time of 150 min/m².

### Comparative Example 6

### <Surface Grinding Process>

An ITO plate-shaped ceramic sintered body having a SnO₂ content of 10% by mass was prepared. One side of this ceramic sintered body was roughly ground with a surface grinding machine manufactured by OKAMOTO CORPORATION using a grindstone with a count of #80 under the conditions of a grindstone rotation speed of 1800 rpm, a depth of cut of 50 μm/pass, and a spark-out of 4 passes. Subsequently, using the same device and a grindstone of count #400, a fine grinding process was carried out under the conditions of a grindstone rotation speed of 1250 rpm, a depth of cut of 10 μm/pass, and a spark-out of 6 passes.

### Comparative Example 7

### <Surface Grinding Process>

A ceramic sintered body having the same composition as that of Comparative Example 6 was prepared, and a disk-shaped sponge polishing material (q 300 mm) with a count of #320 was attached to a Model SDK-P1000NC wet polishing device (polisher) manufactured by Sanwa Diamond Kohan Co., Ltd. to perform surface processing. The grinding conditions were set so that the polisher rotation speed was 120 rpm, the surface pressure (pressing pressure) on the machined surface was 0.58 g/mm², and the grinding time was about 300 min/m². Next, the disc-shaped sponge polishing material was changed to one of count #800, and surface processed under the same conditions.

### Example 3

### <Surface Grinding Process>

A ceramic sintered body having the same composition as that of Comparative Example 6 was prepared, and surface grinding was performed under the same conditions as that of Comparative Example 7.

### <Finishing Process>

Next, a sponge polishing material (Scotch Brite 7448DOT manufactured by 3M) with a count of #800 was attached to a vibration tool (Orbital Sander U-62 manufactured by SAITAMA SEIKI CO., LTD.), and finishing process was performed under the condition of polishing time of 150 min/m².

Table 1 summarizes the processing conditions of each Comparative Example and Example.

TABLE 1

| | | Processing conditions | |
|---|---|---|---|
| | | Surface | |
| | Material | grinding process | Finishing process |
| Comparative | IZO | # 400 count | — |
| Example 1 | | grindstone | |
| Comparative | IZO | # 400 count | Vibration tool |
| Example 2 | | grindstone | (# 800 count sponge |
| | | | polishing material, |
| | | | 150 min/m²) |
| Comparative | IZO | # 800 count | — |
| Example 3 | | grindstone | |
| Reference | IZO | # 400 count | Vibration tool (# 500 |
| Example 1 | | grindstone | & # 800 count sponge |
| | | | polishing material, |
| | | | 1000 min/m²) |
| Comparative | IZO | Polisher processing | — |
| Example 4 | | (# 320 & # 800 count | |
| | | sponge polishing | |
| | | material, 300 min/m²) | |
| Example 1 | IZO | | Vibration tool (# 800 |
| | | | count sponge polishing |
| | | | material, 150 min/m²) |
| Comparative | IZO | Flap wheel | — |
| Example 5 | | (# 800 count sponge | |
| Example 2 | IZO | polishing material) | Vibration tool (# 800 |
| | | | count sponge polishing |
| | | | material, 150 min/m²) |
| Comparative | ITO | # 400 count | — |
| Example 6 | | grindstone | |
| Comparative | ITO | Polisher processing | — |
| Example 7 | | (# 320 & # 800 count | |
| | | sponge polishing | |
| | | material, 300 min/m²) | |
| Example 3 | ITO | | Vibration tool (# 800 |
| | | | count sponge polishing |
| | | | material, 150 min/m²) |

(Measurement of Surface Roughness Ra with a Surface Roughness Meter)

After ultrasonic cleaning of the IZO or ITO sputtering targets of each of the above-processed Examples and Comparative Examples for 5 minutes, a stylus type surface roughness meter (Surftest SJ-301) manufactured by Mitutoyo Corporation was used, and according to the conditions in Table 2 below, Ra was measured at 5 locations on the target surface, and the average value was calculated. The above five locations are four locations near the four corners and one location in the center.

TABLE 2

| Configuration items | Settings |
|---|---|
| Evaluation length (mm) | 4 |
| Measurement speed (mm/s) | 0.5 |
| Measuring force (mN) | ≤4 |
| Number of measurements | 5 |
| (times per location) | |
| Radius of curvature | 5 |
| at tip of stylus | |
| Measurement direction | Parallel to the |
| | grinding direction |

### (Evaluation of Number of Microcracks in Cross Section)

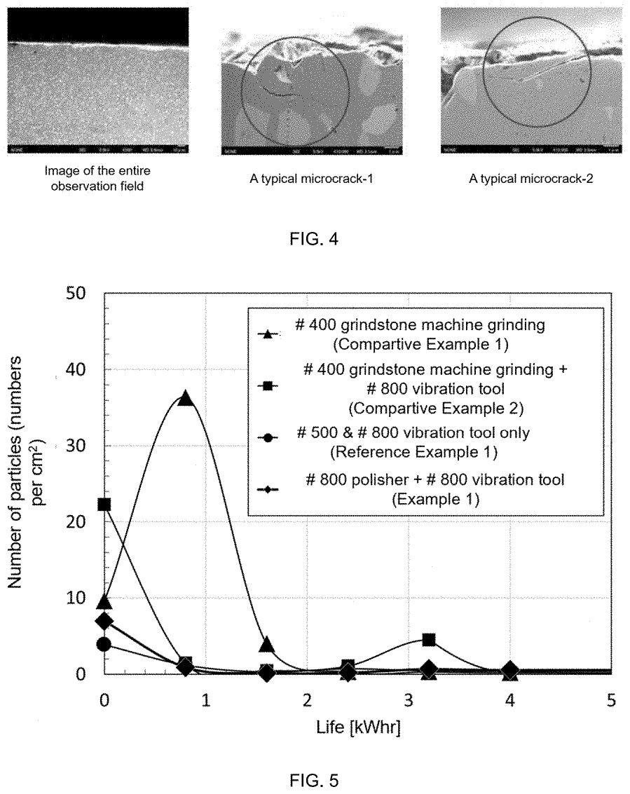

A 20 mm×10 mm size sample was cut out from the IZO or ITO sputtering targets of each of the above-processed Examples and Comparative Examples, and ultrasonically cleaned for 5 minutes. Then, the cross section perpendicular to the sputtering surface was observed with an electron microscope JSM-6700F manufactured by JEOL Ltd., and the number of microcracks per 1 mm in length of the upper end portion on the sputtering surface side was determined (see FIG. 4). The judgment of microcracks was performed on the basis of measuring microcracks having a crack starting point on the machined surface (ground surface) and having a depth of 0.1 μm or more from the machined surface. Further, internal cracks which have no starting point on the machined surface were not counted as microcracks, and even if one microcrack had a plurality of connected branches, it was calculated as one microcrack. Further, even if a starting point was not observed in the observation field of view on the machined surface, those in which the starting point was found on the machined surface in a place other than the observation field of view were counted as microcracks. By this method, measurement was performed along the sputtering surface until a total of 20 cracks were confirmed. The observation magnification can be set freely, but since most microcracks are as small as 0.1 to 20 μm, the magnification is usually about 5000 to 10000 times, and the magnification is preferably adjusted according to the size of the microcracks found. Here, the observation magnification was set to 10,000 times.

### (Evaluation of Depth of Microcracks in Cross Section)

For the microcracks counted as microcracks in the evaluation of the number of microcracks in the cross section, the vertical depth from the sputtering surface of each microcrack was calculated from the image observed by the electron microscope and the scale using the above-mentioned method. The average of the calculated depths for the 20 microcracks was taken as the depth of the microcracks in the cross section. The maximum depth of 20 microcracks in each example was also recorded.

### (Peel Test)

A double-sided carbon tape was attached to the sputtering surface of the target, and the attached portion was rubbed with thumb for about 2 seconds to attach the peeled particles on the target surface to the carbon tape (the area of attachment was set as 100 mm² or more). The above operation was performed three times on the attachment surface of the tape on the same surface of the target (the same tape was attached and peeled off at arbitrary three different places on the surface). The surface (100 mm² or more) of the tape which had been attached to the target was used as the observation surface for observation and photography with an electron microscope, and the area ratio of adhered particles on the observation surface was calculated by an image processing software. The average value of the three fields of view of the same carbon tape sample observed by the above method was defined as the area ratio of the peeled particles by the peel test.

### (Evaluation of Initial Sputtering)

Using the IZO and ITO sputtering targets of each Example and each Comparative Example subjected to the above processing, the following sputtering test was performed after sputtering until the target life became 0.8 kWhr. The film forming conditions were an output of 2.0 kW, a pressure of 0.67 Pa, a gas flow rate of 145 sccm, a film thickness of 55 nm, and an atmosphere of Ar 100%. Then, the number of particles generated on the substrate (wafer) through the sputter life was measured per unit area and evaluated according to the following criteria.

Circle: The maximum number of particles generated per unit area through the initial life (˜5kWhr) is less than 10 particles/cm².
Triangle: The maximum number of particles generated per unit area through the initial life (˜5kWhr) is 10 particles/cm² or more and less than 25 particles/cm².
Cross: The maximum number of particles generated per unit area through the initial life (˜5kWhr) is 25 particles/cm² or more.

Further, for Comparative Examples 1 and 2, and Reference Example 1, and Example 1, the number of particles generated through the sputter life is shown in FIG. 5.

Table 3 shows the evaluation results of the number of particles generated in the sputtering test. As can be seen from Table 3, the number of substrate particles generated was clearly smaller in the Examples than in the Comparative Examples.

TABLE 3

| | | | Evaluation of microcrack | | | | | |
|---|---|---|---|---|---|---|---|---|
| | | | Frequency of | | | Amount of | Peel test | |
| | | Surface | occurrence | | Maximum | microcracks | Peeled | Evaluation |
| | | roughness Ra | (numbers | Depth | depth | (Frequency × | ratio | of initial |
| Conditions | Material | (μm) | per mm) | (μm) | (μm) | Depth) | (%) | sputtering |
| Comparative | IZO | 0.35 | 31.7 | 3.8 | 15.2 | 121 | 1.95 | x |
| Example 1 | | | | | | | | |
| Comparative | IZO | 0.25 | 29.6 | 2.5 | 6.0 | 75 | 0.29 | Δ |
| Example 2 | | | | | | | | |
| Comparative | IZO | 0.18 | 30.9 | 3.0 | 6.3 | 93 | 2.18 | x |
| Example 3 | | | | | | | | |
| Reference | IZO | 0.10 | 21.9 | 0.8 | 1.7 | 18 | 0.14 | ∘ |
| Example 1 | | | | | | | | |
| Comparative | IZO | 0.11 | 12.6 | 1.6 | 3.5 | 28 | 2.47 | Δ |
| Example 4 | | | | | | | | |
| Example 1 | IZO | 0.10 | 9.5 | 1.7 | 2.5 | 16 | 0.22 | ∘ |
| Comparative | IZO | 0.17 | 22.6 | 1.7 | 3.0 | 39 | 2.93 | x |
| Example 5 | | | | | | | | |
| Example 2 | IZO | 0.10 | 14.4 | 1.7 | 2.3 | 24 | 0.19 | ∘ |
| Comparative | ITO | 0.32 | 19.1 | 10.6 | 15.5 | 203 | 11.40 | x |
| Example 6 | | | | | | | | |
| Comparative | ITO | 0.14 | 13.9 | 6.6 | 11.8 | 73 | 0.12 | Δ |
| Example 7 | | | | | | | | |
| Example 3 | ITO | 0.11 | 7.8 | 3.5 | 5.8 | 30 | 0.03 | ∘ |

### (Discussion)

In Comparative Example 1, the surface grinding was only performed with a surface grinding machine using a grindstone with a count of #400, so the amount of microcracks on the machined surface (sputtering surface) exceeded 50 μm/mm, and the peeled ratio by the peel test was also not good. As a result, the evaluation result of initial sputtering was poor.

In Comparative Example 2, the peeled ratio was improved by finishing the machined surface of the surface grinding machine with the vibration tool, but the amount of microcracks was not sufficiently improved, and medium particle generation was observed in the sputtering test.

In Comparative Example 3, although the processing damage could be reduced by changing the grindstone count to #800, the amount of microcracks on the processed surface (sputtering surface) could not be sufficiently reduced, and the amount of microcracks also exceeded 50 μm/mm, and the peeled ratio by the peel test was not good. As a result, the evaluation result of initial sputtering was poor.

Looking at Reference Example 1, as a result of grinding a total of 17 μm or more using #400 sponge polishing material for pretreatment and #500 and #800 sponge polishing material for finishing, it was possible to reduce the amount of microcracks and the amount of peeling by the peel test, and it was possible to obtain a target with few particles during sputtering. However, since the above process takes an enormous amount of time with about 1000 min/m², there is a drawback that it is difficult to apply to mass production.

Looking at Comparative Example 4, it was confirmed that the amount of microcracks could be reduced by the polisher processing, but that alone was insufficient, and it was difficult to remedy the peeled ratio by the peel test without finishing processing.

Looking at Comparative Example 5, it was confirmed that the amount of microcracks can be reduced by using a sponge polishing material instead of a grindstone even with the same count of #800, but that alone was not sufficient, and it was difficult to remedy the peeled ratio by the peel test without finishing processing. As a result, the evaluation result of initial sputtering was poor.

Looking at Examples 1 and 2, it was confirmed that the amount of microcracks could be reduced by using a sponge polishing material with a count of #800, and the amount of peeling by the peel test could be reduced by finishing processing using the vibration tool, so that it was able to obtain a target with few particles during sputtering.

Looking at Comparative Examples 6 and 7 and Example 3, it was confirmed that even if the sputtering target material was changed from IZO to ITO, the same difference and effect could be obtained.

1. A ceramic sputtering target, wherein when a cross-sectional structure of a sputtering surface is observed with an electron microscope, an amount of microcracks defined below is 50 μm/mm or less, and after performing a peel test on the sputtering surface, an area ratio of peeled particles confirmed by observing the cross-sectional structure with an electron microscope is 1.0% or less.
Amount of microcracks=frequency of microcracks×average depth of microcracks

2. The ceramic sputtering target according to claim 1, wherein the amount of microcracks is 40 μm/mm or less.

3. The ceramic sputtering target according to claim 1, wherein the amount of microcracks is 30 μm/mm or less.

4. The ceramic sputtering target according to claim 1, wherein the area ratio of the peeled particles is 0.5% or less.

5. The ceramic sputtering target according to claim 1, wherein the area ratio of the peeled particles is 0.3% or less.

6. The ceramic sputtering target according to claim 1, wherein a surface roughness Ra of the sputtering surface is 0.05 to 0.50 μm.

7. The ceramic sputtering target according to claim 1, comprising at least one of In, Zn, Al, Ga, Zr, Ti, Sn, Mg, Ta, Sm and Si.

8. The ceramic sputtering target according to claim 1, which is an IZO with a Zn content of 1 to 15% by mass in terms of ZnO.

9. The ceramic sputtering target according to claim 1, which is an ITO with a Sn content of 1 to 15% by mass in terms of SnO₂.

10. The ceramic sputtering target according to claim 1, which is an IGZO with an In content of 10 to 60% by mass in terms of In₂O₃, a Ga content of 10 to 60% by mass in terms of Ga₂O₃, and a Zn content of 10 to 60% by mass in terms of ZnO.

11. The ceramic sputtering target according to claim 1, which is an AZO with an Al content of 0.1 to 5% by mass in terms of Al₂O₃.

12. A method for manufacturing a ceramic sputtering target, comprising:
a step of preparing a ceramic sintered body;
a step of surface grinding the ceramic sintered body using a sponge polishing material having a count of #300 or more and #1000 or less; and
a step of forming a sputtering surface by finishing processing the ceramic sintered body using a vibration tool after the surface grinding.

13. The method for manufacturing a ceramic sputtering target according to claim 12, wherein when a cross-sectional structure of the sputtering surface after the finishing processing is observed with an electron microscope, an amount of microcracks defined below is 50 μm/mm or less, and after performing a peel test on the sputtering surface, an area ratio of peeled particles confirmed by observing the cross-sectional structure with an electron microscope is 1.0% or less.
Amount of microcracks=frequency of microcracks×average depth of microcracks

14. The method for manufacturing a ceramic sputtering target according to claim 13, wherein the amount of microcracks is 40 μm/mm or less.

15. The method for manufacturing a ceramic sputtering target according to claim 13, wherein the amount of microcracks is 30 μm/mm or less.

16. The method for manufacturing a ceramic sputtering target according to claim 13, wherein the area ratio of the peeled particles is 0.5% or less.

17. The method for manufacturing a ceramic sputtering target according to claim 13, wherein the area ratio of the peeled particles is 0.3% or less.

18. The method for manufacturing a ceramic sputtering target according to claim 12, wherein a surface roughness Ra of the sputtering surface after the finishing processing is 0.05 to 0.50 μm.

19. The method for manufacturing a ceramic sputtering target according to claim 12, wherein the ceramic sputtering target comprises at least one of In, Zn, Al, Ga, Zr, Ti, Sn, Mg, Ta, Sm and Si.

20. The method for manufacturing a ceramic sputtering target according to claim 12, wherein the ceramic sputtering target is an IZO with a Zn content of 1 to 15% by mass in terms of ZnO.

21. The method for manufacturing a ceramic sputtering target according to claim 12, wherein the ceramic sputtering target is an ITO with a Sn content of 1 to 15% by mass in terms of SnO₂.

22. The method for manufacturing a ceramic sputtering target according to claim 12, wherein the ceramic sputtering target is an IGZO with an In content of 10 to 60% by mass in terms of In₂O₃, a Ga content of 10 to 60% by mass in terms of Ga₂O₃, and a Zn content of 10 to 60% by mass in terms of ZnO.

23. The method for manufacturing a ceramic sputtering target according to claim 12, wherein the ceramic sputtering target is an AZO with an Al content of 0.1 to 5% by mass in terms of Al₂O₃.
